(19) United States
(12) Patent Application Publication
(10) Pub. No.: US 2026/0040652 A1
(43) Pub. Date: Feb. 5, 2026

(54) SPLIT DOUBLE GATE TRANSISTOR AND METHOD FOR MANUFACTURING THE SAME

(71) Applicants: Materials Analysis Technology Inc., Hsinchu County (TW); NATIONAL TAIWAN UNIVERSITY, TAIPEI CITY (TW)

(72) Inventors: Chee-Wee Liu, Taipei City (TW); Rachit Dobhal, Taipei City (TW); Yu-Shan Wu, New Taipei City (TW); Jih-Chao Chiu, New Taipei City (TW); HUNG-JEN CHEN, Hsinchu City (TW)

(21) Appl. No.: 19/268,992

(22) Filed: Jul. 14, 2025

Related U.S. Application Data
(60) Provisional application No. 63/677,400, filed on Jul. 30, 2024.

(51) Int. Cl. H10D 64/27; H10D 30/00; H10D 30/01

(52) U.S. Cl. CPC H10D 64/518; H10D 30/0195; H10D 30/501

(57) ABSTRACT

A method for manufacturing a split double gate transistor includes: forming a first fin on a substrate; removing sacrificial layers from a portion of the first fin; sequentially forming a first gate insulating layer, a channel layer and a protection layer on exposed portions of each gate metal layer; performing a patterning process to form a second fin; patterning the second fin to form a plurality of first recesses and a plurality of second recesses; forming a plurality of inner spacer layers; forming a first gate component, a drain component and a source component; removing the protection layer; and sequentially forming a second gate insulating layer, a plurality of gate connectors, and a second gate component.

CROSS-REFERENCE TO RELATED PATENT APPLICATION

This application claims the benefit of priority to the U.S. Provisional Patent Application Ser. No. 63/677,400, filed on Jul. 30, 2024, which application is incorporated herein by reference in its entirety.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a device and a manufacturing method, and more particularly to a split double gate transistor and a method for manufacturing the same.

### BACKGROUND OF THE DISCLOSURE

To reduce transistor sizes, improve circuit density and enhance both current drive capability and power efficiency, stacked nanowire or nanosheet transistors are being rapidly developed and adopted at a 3 nm technology node and beyond, including upcoming nodes such as 2 nm, 1.4 nm, and potentially sub-1 nm nodes in the future.

The stacked nanowire and nanosheet transistor is a representative implementation of a Gate-All-Around (GAA) architecture. In the stacked nanowire and nanosheet transistor, a channel is fully surrounded by gate material. As a result, the stacked nanowire and nanosheet transistor offers better electrostatic control, significantly reduced short channel effects (SCE), and improved switching characteristics including higher on/off current ratios.

However, in a fabrication process of the Gate-All-Around (GAA) architecture, a channel layer is typically epitaxially grown in a stacked configuration sequentially, meaning each nanowire or nanosheet channel is formed layer by layer. In this multi-stage process, temperature fluctuations, gas flow changes, uneven material supply or insufficient etching selectivity in any of the processes may lead to significant errors in thickness, crystal quality, stress distribution and doping concentration between those channel layers. These process variations directly affect carrier mobility of the channel layers, consistency of the threshold voltages, and overall electrical performance stability of the stacked nanowire and nanosheet transistors, thereby leading to a decrease in yield and unpredictability of product performance during large-scale manufacturing.

Furthermore, conventional GAA architectures do not accommodate back gates, making their implementation in such architectures a significant challenge. In conventional field-effect transistors (FETs), back gates are commonly employed to dynamically modulate carrier concentration within the channels, enabling flexible tuning of critical voltages. However, since the channels of the conventional GAA architectures are completely surrounded by the gate materials, there is no extra space within the channels to accommodate the back electrodes. As a result, the conventional GAA architectures cannot employ back-biasing techniques to finely control the critical voltages thereof.

### SUMMARY OF THE DISCLOSURE

In response to the above-referenced technical inadequacies, the present disclosure provides a split double gate transistor and a method for manufacturing the same.

In order to solve the above-mentioned problems, one of the technical aspects adopted by the present disclosure is to provide the method for manufacturing the split double gate transistor. The method includes processes of: forming a first fin including a plurality of gate metal layers and a plurality of sacrificial layers that are stacked alternately on a substrate; removing the plurality of sacrificial layers from a portion of the first fin; sequentially forming a first gate insulating layer, a channel layer and a protection layer on an exposed portion of each of the plurality of gate metal layers; patterning the first fin, the first gate insulating layer, the channel layer and the protection layer to form a second fin; patterning the second fin to form a plurality of first recesses on a first side and a second side and a plurality of second recesses on a third side and a fourth side; forming a plurality of inner spacer layers to fill in the plurality of first recesses and the plurality of second recesses; forming a first gate component connected electrically to the plurality of gate metal layers on the first side, a drain component connected electrically to the channel layer on the third side, and a source component connected electrically to the channel layer on the fourth side; removing a portion of the plurality of inner spacer layers and each of the protection layers from the second side, to expose each of the plurality of gate metal layers, the first gate insulating layer, the channel layer, and each of the plurality of inner spacer layers that are not removed; and sequentially forming a second gate insulating layer, a plurality of gate connectors and a second gate component, on each of the plurality of gate metal layers, the first gate insulating layer and the channel layer that are exposed, and on each of the plurality of inner spacer layers that are not removed.

In order to solve the above-mentioned problems, one of the technical aspects adopted by the present disclosure is to provide the split double gate transistor. The split double gate transistor includes a substrate, a fin-shaped structure, a fin-shaped structure, a drain component and a source component and a second gate component. The fin-shaped structure is disposed on the substrate. The fin-shaped structure includes the fin-shaped structure, a plurality of gate connectors, a plurality of inner spacers and a second gate insulating layer. The plurality of stacked structures are arranged at intervals along a vertical direction. Each of the plurality of stacked structures includes a gate metal layer, a first gate insulating layer and a channel layer. The plurality of gate connectors are arranged alternately with the plurality of stacked structures along the vertical direction, and extend along a first direction. The plurality of inner spacers are spaced apart from each other along the vertical direction, respectively surround the plurality of gate connectors, and are in contact with the first gate insulating layer and the channel layer. The second gate insulating layer is disposed between the plurality of inner spacers and the plurality of gate connectors and between the plurality gate connectors and the plurality stacked structures. The first gate component is disposed on a first side of the fin-shaped structure and electrically connected to the gate metal layer. The drain component is disposed on a second side opposite to the fin-shaped structure along a second direction, and electrically connected to a drain region of the channel layer. The source component is disposed on a third side opposite to the fin-shaped structure along the second direction, and electrically connected to a source region of the channel layer. The second gate component is disposed on the second side of the fin-shaped structure and electrically connected to the plurality of gate connectors.

These and other aspects of the present disclosure will become apparent from the following description of the embodiment taken in conjunction with the following drawings and their captions, although variations and modifications therein may be effected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a flowchart diagram of a method for manufacturing a split double gate transistor according to a first embodiment of the present disclosure;

FIG. 2 is a top view of process S10 according to the first embodiment of the present disclosure;

FIG. 3 is a first cross-sectional view of process S10 according to the first embodiment of the present disclosure;

FIG. 4 is a second cross-sectional view of process S10 according to the first embodiment of the present disclosure;

FIG. 5 is a top view of process S11 according to the first embodiment of the present disclosure;

FIG. 6 is a first cross-sectional view of process S11 according to the first embodiment of the present disclosure;

FIG. 7 is a second cross-sectional view of process S11 according to the first embodiment of the present disclosure;

FIG. 8 is a first top view of process S12 according to the first embodiment of the present disclosure;

FIG. 9 is a first cross-sectional view of process S12 according to the first embodiment of the present disclosure;

FIG. 10 is a second cross-sectional view of process S12 according to the first embodiment of the present disclosure;

FIG. 11 is a second top view of process S12 according to the first embodiment of the present disclosure;

FIG. 12 is a third cross-sectional view of process S12 according to the first embodiment of the present disclosure;

FIG. 13 is a fourth cross-sectional view of process S12 according to the first embodiment of the present disclosure;

FIG. 14 is a top view of process S13 according to the first embodiment of the present disclosure;

FIG. 15 is a first cross-sectional view of process S13 according to the first embodiment of the present disclosure;

FIG. 16 is a second cross-sectional view of process S13 according to the first embodiment of the present disclosure;

FIG. 17 is a detailed flowchart diagram of process S14;

FIG. 18 is a top view of process S14 according to the first embodiment of the present disclosure;

FIG. 19 is a first cross-sectional view of process S14 according to the first embodiment of the present disclosure;

FIG. 20 is a second cross-sectional view of process S14 according to the first embodiment of the present disclosure;

FIG. 21 is a top view of process S15 according to the first embodiment of the present disclosure;

FIG. 22 is a first cross-sectional view of process S15 according to the first embodiment of the present disclosure;

FIG. 23 is a second cross-sectional view of process S15 according to the first embodiment of the present disclosure;

FIG. 24 is a top view of process S16 according to the first embodiment of the present disclosure;

FIG. 25 is a first cross-sectional view of process S16 according to the first embodiment of the present disclosure;

FIG. 26 is a second cross-sectional view of process S16 according to the first embodiment of the present disclosure;

FIG. 27 is a top view of processes S17 and S18 according to the first embodiment of the present disclosure;

FIG. 28 is a first cross-sectional view of processes S17 and S18 according to the first embodiment of the present disclosure;

FIG. 29 is a second cross-sectional view of processes S17 and S18 according to the first embodiment of the present disclosure;

FIG. 30 is a top view of process S 19 according to the first embodiment of the present disclosure;

FIG. 31 is a first cross-sectional view of process S19 according to the first embodiment of the present disclosure;

FIG. 32 is a second cross-sectional view of process S19 according to the first embodiment of the present disclosure;

FIG. 33 is a top view of process S20 according to the first embodiment of the present disclosure;

FIG. 34 is a first cross-sectional view of process S20 according to the first embodiment of the present disclosure;

FIG. 35 is a second cross-sectional view of process S20 according to the first embodiment of the present disclosure;

FIG. 36 is a perspective view of a split double gate transistor according to a second embodiment of the present disclosure; and

FIG. 37 is a perspective view of the split double gate transistor from which a second gate component is removed according to the second embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

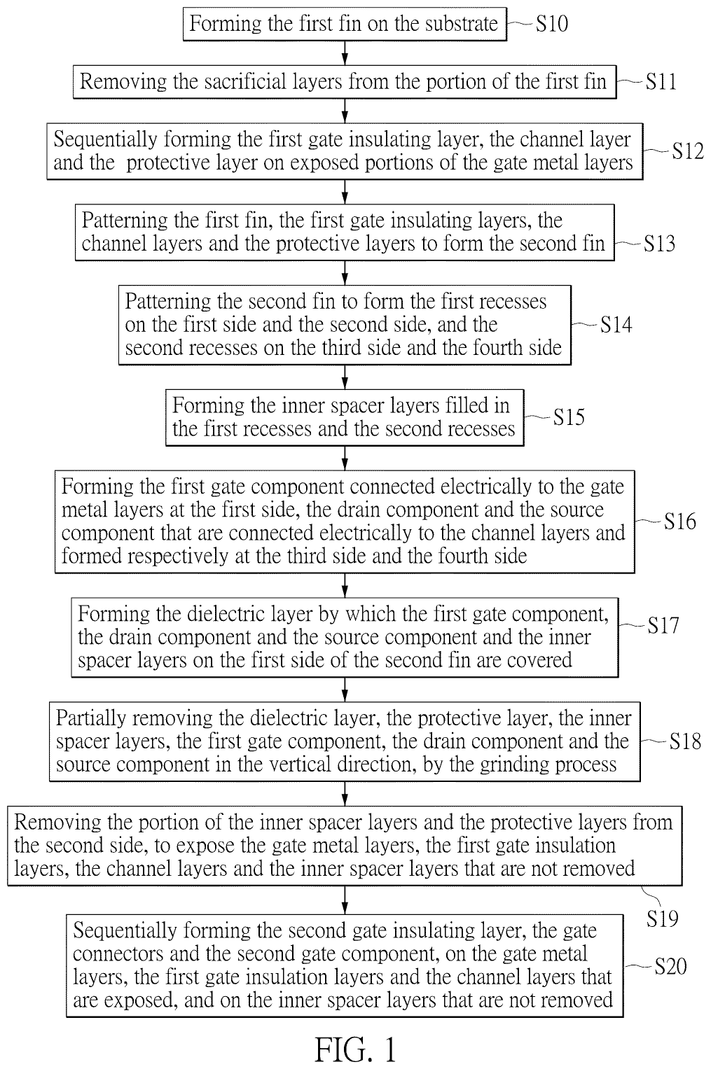

Reference is made to FIG. 1, which is a flowchart diagram of a method for manufacturing a split double gate transistor according to a first embodiment of the present disclosure. The method of FIG. 1 is shown for illustration, but other processes may be performed before, during, or after the method of FIG. 1.

As shown in FIG. 1, the first embodiment of the present disclosure provides the method for manufacturing the split double gate transistor, which includes processes S10 to S20.

In process S10, a first fin is formed on a substrate.

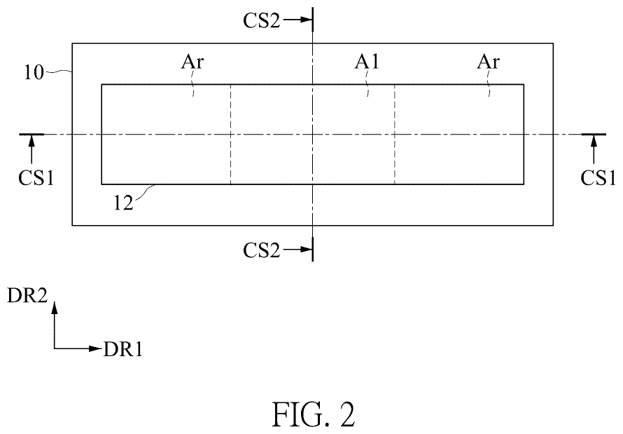

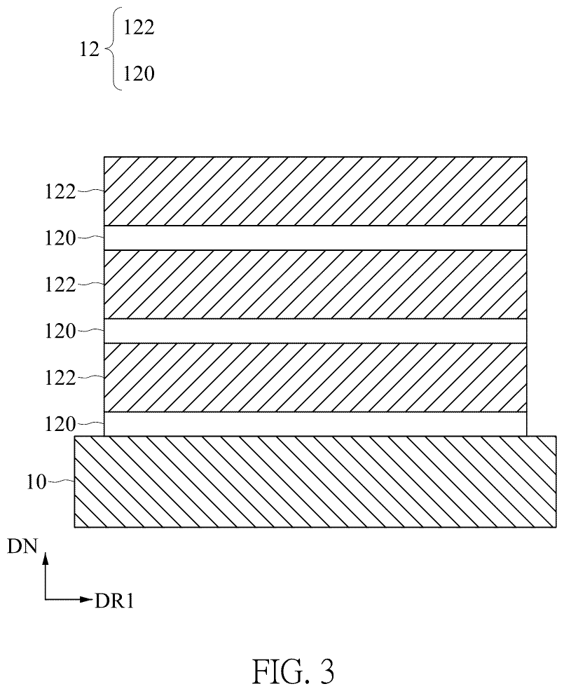

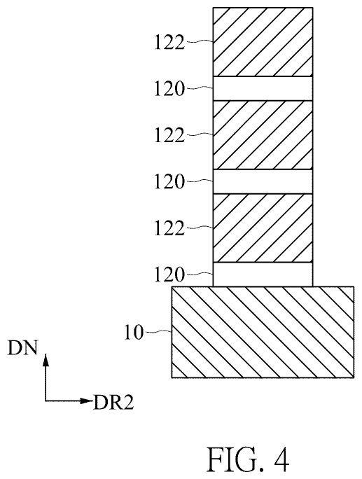

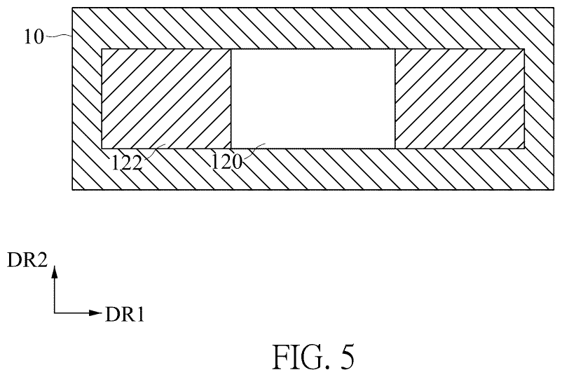

Reference is made to FIGS. 2 to 4, in which FIG. 2 is a top view of process S10 according to the first embodiment of the present disclosure, FIG. 3 is a first cross-sectional view of process S10 according to the first embodiment of the present disclosure, FIG. 4 is a second cross-sectional view of process S10 according to the first embodiment of the present disclosure, and FIG. 5 is a top view of process S11 according to the first embodiment of the present disclosure.

FIG. 3 is a first cross-sectional view taken along a section line CS1. FIG. 4 is a second cross-sectional view taken along a section line CS2. The remaining cross-sectional views, unless otherwise specified, are captured along the cross-sectional lines CS1 and CS2, and are not repeatedly shown.

A substrate 10 may include silicon, germanium, glass or other materials. A first region A1 and redundant regions Ar on two sides of the first region A1 of the substrate 10 are defined. The first fin 12 covers the first region A1 and the adjacent regions Ar on both sides of the first region A1 of the substrate 10. The first fin 12 extends along a vertical direction DN. A first direction DR1, a second direction DR2 and the vertical direction DN are perpendicular to each other. The first region A1 and the redundant regions Ar may be arranged along the first direction DR1. For example, the first region A1 is a rectangular region. A width of the first region A1 in the second direction DR2 is shorter than a length of the first region A1 in the first direction DR1.

The first fin 12 includes a plurality of gate metal layers 120 and a plurality of sacrificial layers 122 that are alternately stacked along the vertical direction DN. For example, a first one of the plurality of gate metal layers 120 is disposed on the substrate 10, a first one of a plurality of sacrificial layers 122 is disposed on the first one of the plurality of gate metal layers 120, and then a second one of the plurality of gate metal layers 120 is disposed on the first one of the plurality of sacrificial layers 122, and so on. The three gate metal layers 120 and three sacrificial layers 122 that are alternately stacked are exemplified as below. In some embodiments, the gate metal layers 120 and the sacrificial layers 122 have different thicknesses. Furthermore, one of the gate metal layers 120 may have a different thickness from another of the gate metal layers 120, and one of the sacrificial layers 122 may have a different thickness from another of the sacrificial layers 122.

The gate metal layer 120 may include titanium nitride (TiN), tungsten, aluminum or titanium, and may have a thickness falling within a range of 1 nm to 1000 nm. The gate metal layer 120 may be formed by atomic layer deposition (ALD) or physical vapor deposition (PVD). In addition, the sacrificial layer 122 may include titanium nitride, titanium, tungsten, silicon nitride, silicon dioxide, other materials or any combination thereof, and may have a thickness falling within a range of 1 nm to 1 μm. The sacrificial layer 122 may be deposited using ALD, sputtering, plasma-enhanced chemical vapor deposition (PECVD), or an epitaxial growth.

In process S10, the three gate metal layers 120 and the three sacrificial layers 122 may be alternately stacked and sequentially formed on the substrate 10, for example, by ALD or sputtering. Then, a mask defining a fin pattern is formed on a top surface of a stacked structure of the three gate metal layers 120 and the three sacrificial layers 122, for example, by e-beam lithography. Then, a portion of the stacked structure that is not covered by the mask is removed, for example, by using reactive ion etching (RIE), and the mask is finally removed for obtaining a fin-shaped structure.

In process S11, the sacrificial layers are removed from a portion of the first fin.

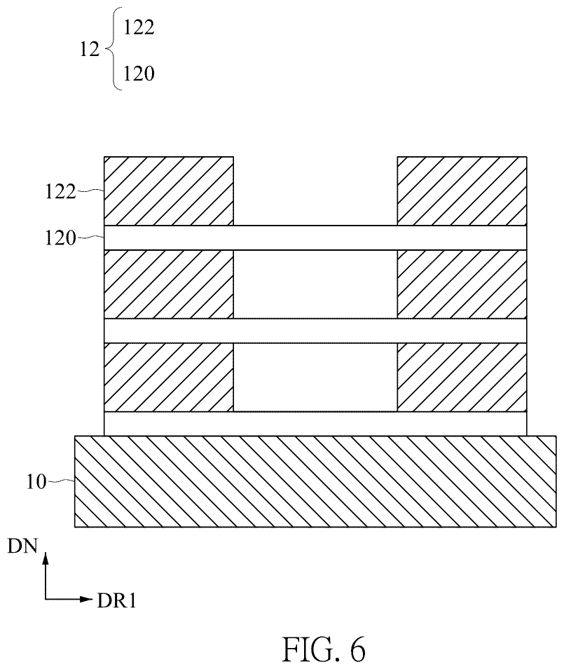

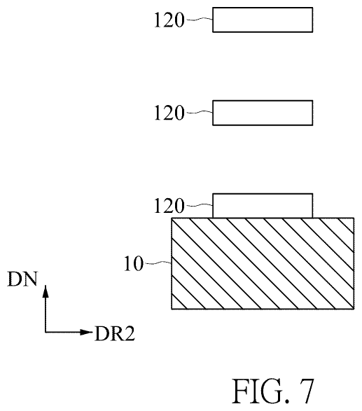

Reference is made to FIGS. 5 to 7, in which FIG. 5 is a top view of process S11 according to the first embodiment of the present disclosure, FIG. 6 is a first cross-sectional view of process S11 according to the first embodiment of the present disclosure, and FIG. 7 is a second cross-sectional view of process S11 according to the first embodiment of the present disclosure.

In process S11, a portion of the sacrificial layer 122 that is located outside the first region A1 may be removed from the first fin 12, thereby exposing a portion of each gate metal layer 120.

For example, a portion of the sacrificial layer 122 that overlaps the first region A1 may be removed by selective etching, such that the portion of the gate metal layer 120 in the same region is exposed. A second one and a third one of the plurality of gate metal layers 120 are supported by a remaining portion of the sacrificial layer 122 that is not removed from the redundant region Ar. As a result, portions of the second and third ones of the plurality of gate metal layers 120 in the first region A1 are suspended above the substrate 10.

In process S12, a first gate insulating layer, a channel layer and a protection layer are sequentially formed on the exposed portion of each gate metal layer.

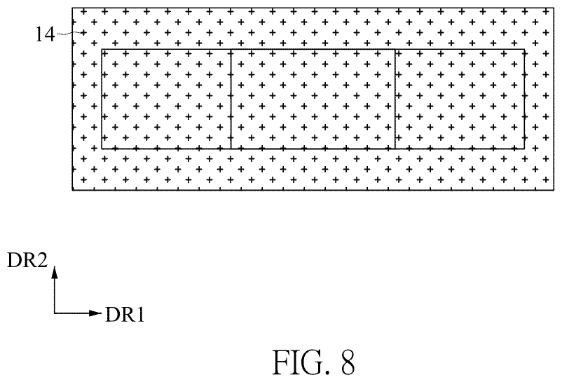

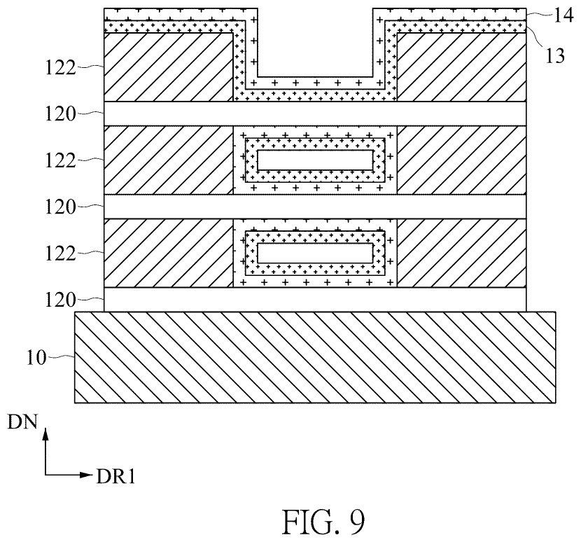

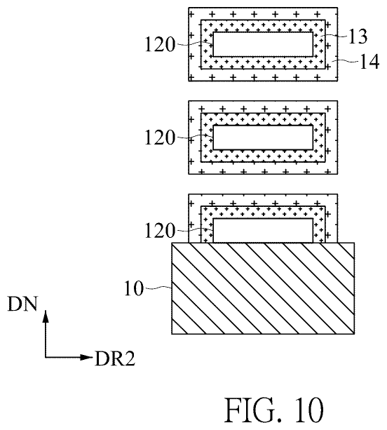

Reference is made to FIGS. 8 to 10, in which FIG. 8 is a first top view of process S12 according to the first embodiment of the present disclosure, FIG. 9 is a first cross-sectional view of process S12 according to the first embodiment of the present disclosure, and FIG. 10 is a second cross-sectional view of process S12 according to the first embodiment of the present disclosure.

Each first gate insulating layer 13 may include a high-k dielectric material such as aluminum oxide (A1₂O₃), hafnium oxide (HfO₂), zirconium oxide (ZrO₂) or hafnium zirconium oxide (HZO). A thickness of the first gate insulating layer 13 may fall within a range of 1 nm to 1000 nm, and may be deposited by ALD or another technology.

Each channel layer 14 may include oxide semiconductor materials, II-VI group, III-V group, IV group, two-dimensional materials (2D materials), and so on. The channel layer 14 may be deposited by ALD or another technology, and may be applicable to oxide semiconductor materials such as InO, IZO, ITO, IWO, IGZO, IGZTO and so on. In some cases, in order to realize etching selectivity, the materials of the channel layer 14 (such as IGZO) must be different from that of the sacrificial layer 122 (such as SiO₂, SiN, TiN, W, Ti).

As shown in FIG. 8, the first gate insulating layer 13 and the channel layer 14 sequentially cover the substrate 10, a top surface of an uppermost one of the plurality of sacrificial layers 122, and an exposed portion of an uppermost one of the plurality of gate metal layers 120.

As shown in FIG. 9, the first gate insulating layer 13 and the channel layer 14 cover a lowermost one of the plurality of gate metal layers 120, and are sequentially formed to surround the gate metal layers 120 that are suspended, especially top surfaces, side surfaces and bottom surfaces of the third one and the second one of the plurality of gate metal layers 120.

As shown in FIG. 10, the first gate insulating layer 13 and the channel layer 14 further cover an inner surface of the sacrificial layer 122 that is exposed in the process S11 such that a double-layer rectangular structure having a hollow portion is formed between a first one and the second one of the plurality of gate metal layers 120, and a concave portion is correspondingly formed on the third one of the plurality of gate metal layer 120.

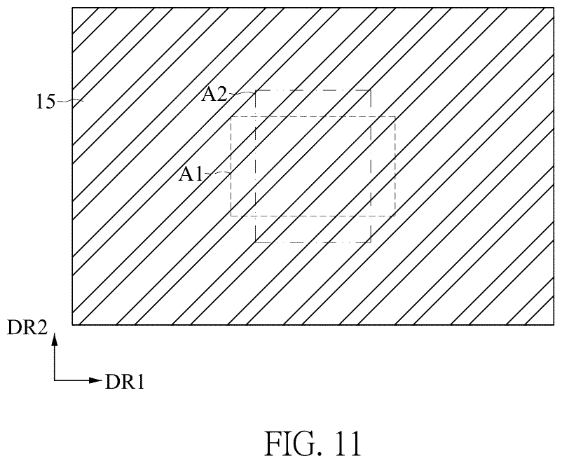

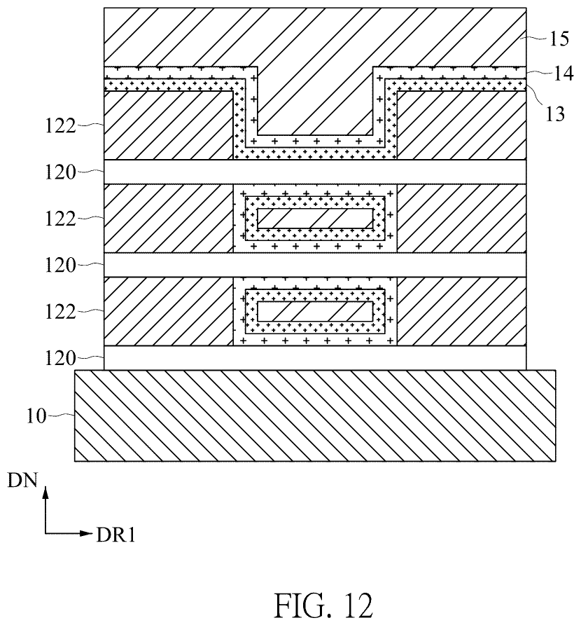

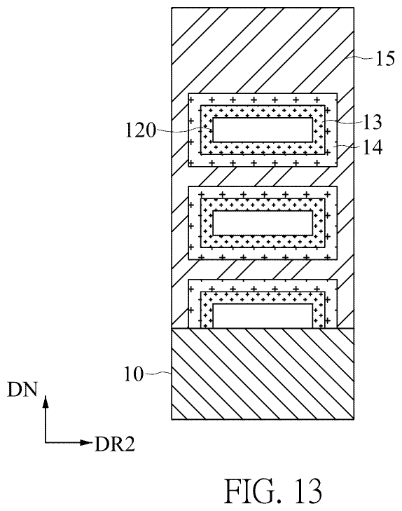

Reference is made to FIGS. 11 to 13, in which FIG. 11 is a second top view of process S12 according to the first embodiment of the present disclosure, FIG. 12 is a third cross-sectional view of process S12 according to the first embodiment of the present disclosure, and FIG. 13 is a fourth cross-sectional view of process S12 according to the first embodiment of the present disclosure.

As shown in FIG. 11 to FIG. 13, after the first gate insulating layer 13 and the channel layer 14 are formed, a protection layer 15 may be formed. For example, the protection layer 15 may include silicon oxide (SiOx), and may be deposited by the PECVD, thermal oxidation or ALD.

As shown in FIG. 9, a stacked structure in which the channel layer 14, the first gate insulating layer 13 and the gate metal layer 120 are sequentially stacked is completely surrounded by the protection layer 15.

As shown in FIG. 8 and FIG. 10, the protection layer 15 covers a stacked structure in which the channel layer 14 and the first gate insulating layer 13 are sequentially stacked above the third one of the plurality of the gate metal layers 120 and a third one of the plurality of sacrificial layers 122, the hollow portions in the double-layer rectangular structure shown in FIG. 7, and the recessed portion that is correspondingly formed above the third one of the plurality of the gate metal layer 120.

In some embodiments, a thickness of the protection layer 15 in the second direction DR2 is different from that in the vertical direction DN.

In process S12, all of the channel layers 15 may be formed simultaneously in a designed single procedure. Therefore, compared with sequentially grown channel layers in a conventional stacked nanowire or nanosheet structure, process variation between the channel layers 14 in the present disclosure is minimized, thereby ensuring improved consistency in electron mobilities, threshold voltages and overall transistor performance.

In process S13, the first fin, each first gate insulating layer, each channel layer and each protection layer are patterned to form a second fin.

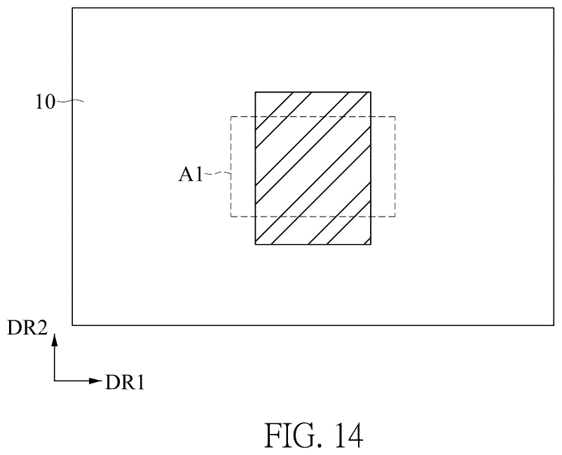

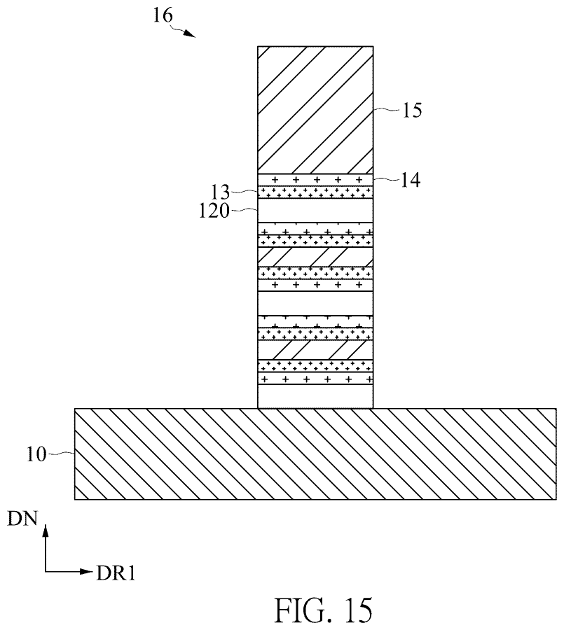

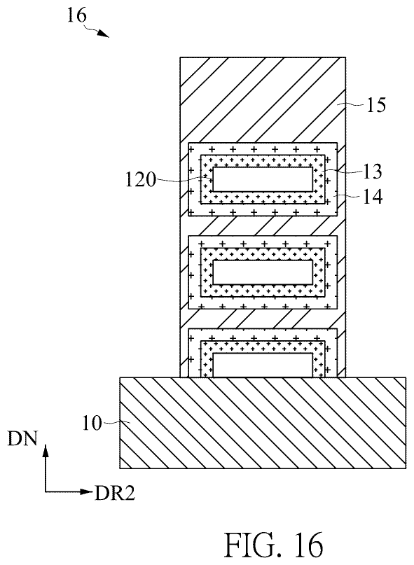

Reference is made to FIGS. 14 to 16, in which FIG. 14 is a top view of process S13 according to the first embodiment of the present disclosure, FIG. 15 is a first cross-sectional view of process S13 according to the first embodiment of the present disclosure, and FIG. 16 is a second cross-sectional view of process S13 according to the first embodiment of the present disclosure.

In detail, in process S13, portions of the first fin 12, the first gate insulating layer 13, the channel layer 14 and the protection layer 15 that are located outside the second region A2 of the substrate 10 may be removed, such that a remaining portion in the second region A2 forms a second fin 16. For example, the second region A2 may be a rectangular region partially overlapping the first region A1. A length of the second region A2 in the first direction DR1 is smaller than the length of the first region A1 in the same direction. More specifically, the length of the second region A2 in the first direction DR1 is less than or equal to the length of the first region A1 in the same direction, minus twice the thickness of the first gate insulating layer 13 and twice the thickness of the channel layer 14. In addition, a width of the second region A2 in the second direction DR2 is larger than a width of the first region A1 in the second direction DR2. More specifically, the width of the second region A2 in the second direction DR2 is greater than or equal to the width of the first region A1 in the same direction, plus twice the thicknesses of the first gate insulating layer 13, the channel layer 14 and the protection layer 15, each measured in the first direction DR1.

It is apparent that, according to the above-size definition of the first region A1 and the second region A2, the portions of the first fin 12, the first gate insulating layer 13, the channel layer 14 and the protection layer 15 that are located outside the second region A2 of the substrate 10 are removed, the side surfaces of the gate metal layers 120, the first gate insulating layer 13 and the channel layer 14 are exposed along the first direction DR1, while their side surfaces in the second direction DR2 remain covered by the protection layer 15.

For example, in this embodiment, the second fin 16 is formed with a stack of layers arranged sequentially from bottom to top as follows: a gate metal layer 120, a first gate insulating layer 13, a channel layer 14, a protection layer 15, a channel layer 14, a first gate insulating layer 13, a gate metal layer 120, a first gate insulating layer 13, a channel layer 14, a protection layer 15, a channel layer 14, a first gate insulating layer 13, a gate metal layer 120, and a protection layer 15. In addition, two sides of the second fin 16 along the first direction DR1 are defined as the first side and the second side, while two sides of the second fin 16 along the second direction DR2 are defined as the third side and the fourth side.

In process S14, the second fin 16 is patterned to form a plurality of first recesses on the first and second sides, and a plurality of second recesses on the third and fourth sides.

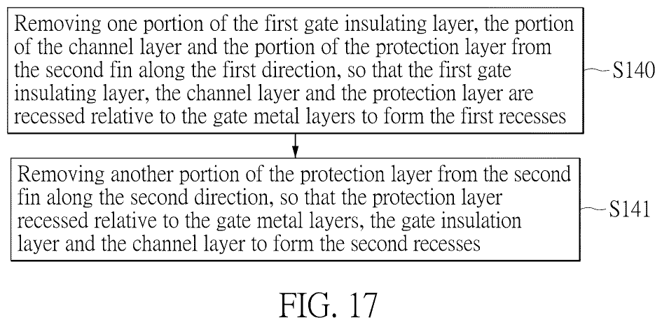

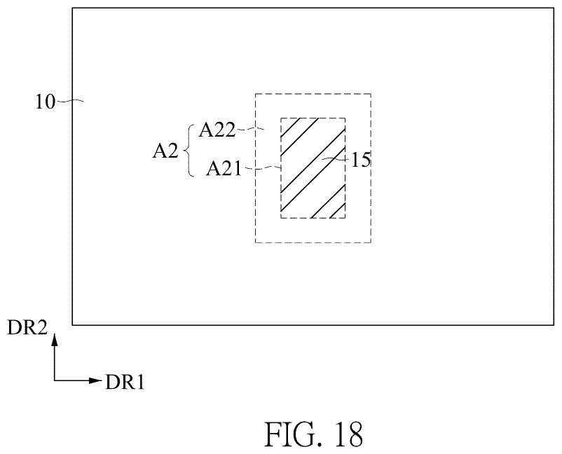

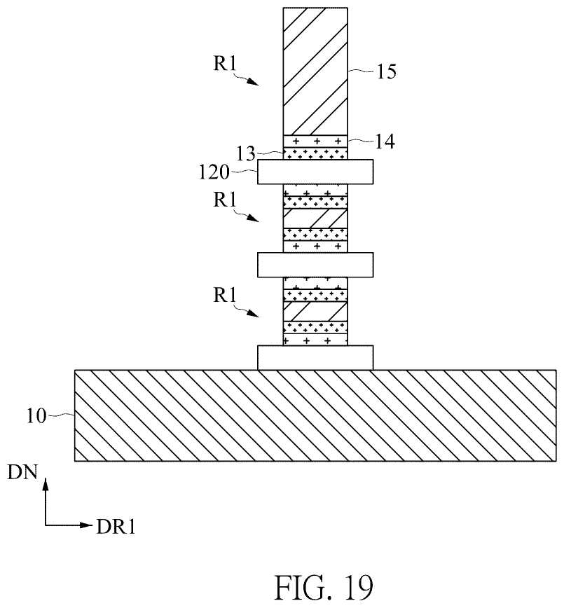

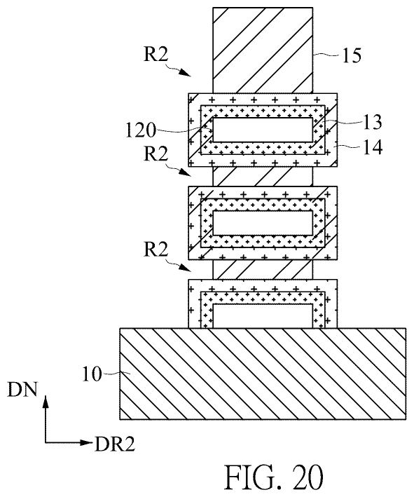

Reference is made to FIGS. 17 to 20, in which FIG. 17 is a detailed flowchart diagram of process S14, FIG. 18 is a top view of process S14 according to the first embodiment of the present disclosure, FIG. 19 is a first cross-sectional view of process S14 according to the first embodiment of the present disclosure, and FIG. 20 is a second cross-sectional view of process S14 according to the first embodiment of the present disclosure.

In some embodiments, process S14 include processes S140 and S141.

In process S140, portions of the gate insulating layer, the channel layer and the protection layer are removed from the second fin along the first direction, so that these layers are recessed beyond the plurality of gate metal layers, thereby forming the plurality of first recesses.

As shown in FIGS. 18 to 20, the second region A2 may include an inner region A21 and an outer region A22 surrounding the inner region A21. In process S140, portions of the first gate insulating layer 13, the channel layer 14, and the protection layer 15 that overlap with the outer region A22 of the second fin 16 along the first direction DR1 are removed by reactive ion etching (RIE), plasma etching, atomic layer etching (ALE), wet etching, and/or another technology, so that the first gate insulating layer 13, the channel layer 14 and the protection layer 15 are recessed beyond the gate metal layer 120 to form the plurality of first recesses R1. That is, the upper and lower surfaces of each gate metal layer 120 are partially exposed, and the two side surfaces of each gate metal layer 120 along the first direction DR1 protrude beyond the stacked structure of the first gate insulating layer 13, the channel layer 14 and the protection layer 15 that are disposed adjacent thereto.

In process S141, another portion of the protection layer is removed from the second fin along the second direction, so that the protection layer is recessed beyond the plurality of gate metal layers, the gate insulating layer and the channel layer to form the plurality of second recesses.

As shown in FIGS. 18 to 20, in process S141, selective etching, such as reactive ion etching (RIE), plasma etching, atomic layer etching (ALE), and/or wet etching, may be used to remove a portion of the protection layer 15 overlapping the outer region A22 of the second fin 16 along the second direction DR2. As a result, the protection layer 15 is recessed beyond the gate metal layer 120, the first gate insulating layer 13 and the channel layer 14 to form the plurality of second recesses R2.

That is, the outer surfaces of the plurality of channel layers 14 formed around the gate metal layer 120 are partially exposed, and two of the outer surfaces of each channel layer 14 protrude beyond the protection layer 15 formed adjacent thereto along the second direction DR2. In addition, two outer side surfaces of each first gate insulating layer 13 formed around the gate metal layer 120 also protrude beyond the protection layer 15 disposed adjacent thereto along the second direction DR2.

In process S15, a plurality of inner spacer layers are formed to fill the plurality of first recesses and the plurality of second recesses.

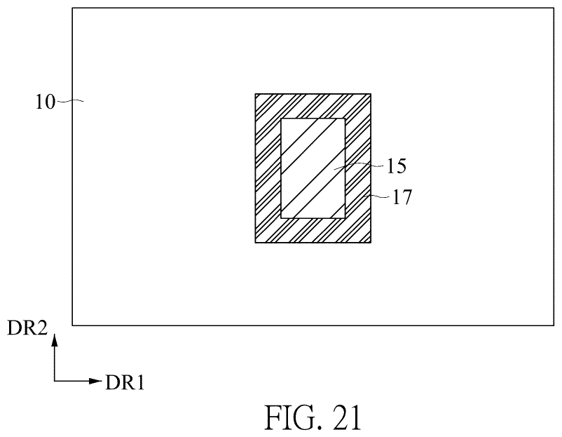

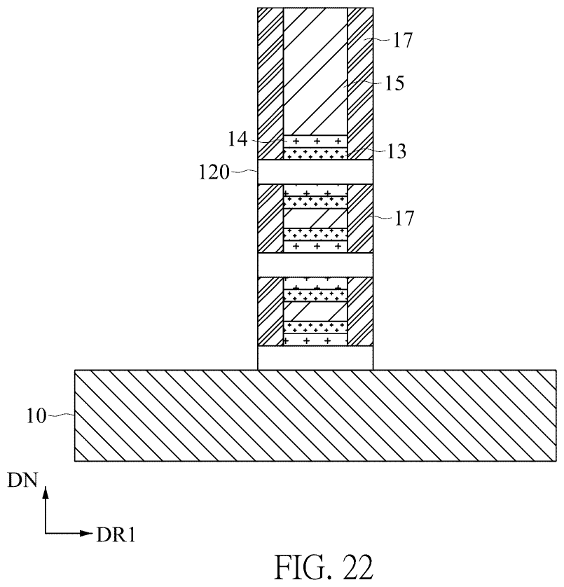

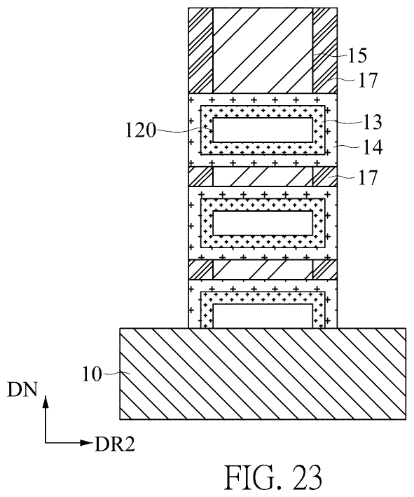

Reference is made to FIGS. 21 to FIG. 23, in which FIG. 21 is a top view of process S15 according to the first embodiment of the present disclosure, FIG. 22 is a first cross-sectional view of process S15 according to the first embodiment of the present disclosure, and FIG. 23 is a second cross-sectional view of process S15 according to the first embodiment of the present disclosure.

As shown in FIGS. 21 and 22, the inner spacer layer 17 surrounds the plurality of first gate insulating layers 13, the plurality of channel layers 14, and the plurality of protection layers 15, while exposing two side surfaces of each gate metal layer 120 along the first direction DR1, and completely fills the plurality of first recesses R1. As shown in FIGS. 21 and 23, the inner spacer layer 17 surrounds each protection layer 15, while exposing two outer side surfaces of each channel layer 14 along the second direction DR2, and completely fills the plurality of second recesses R2.

In process S15, the inner spacer layer 17 may include silicon nitride (Si₃N₄), silicon oxide (SᵢO₂), silicon oxynitride (SiON) or other materials, and may be deposited by atomic layer deposition (ALD), sputtering or plasma-enhanced chemical vapor deposition (PECVD).

In process S16, the first gate component is formed on the first side and electrically connected to the plurality of gate metal layers, and the drain component and the source component are formed respectively on the third side and the fourth side and electrically connected to each channel layer.

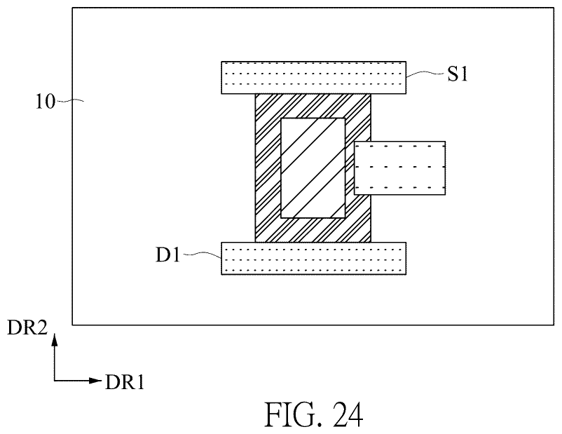

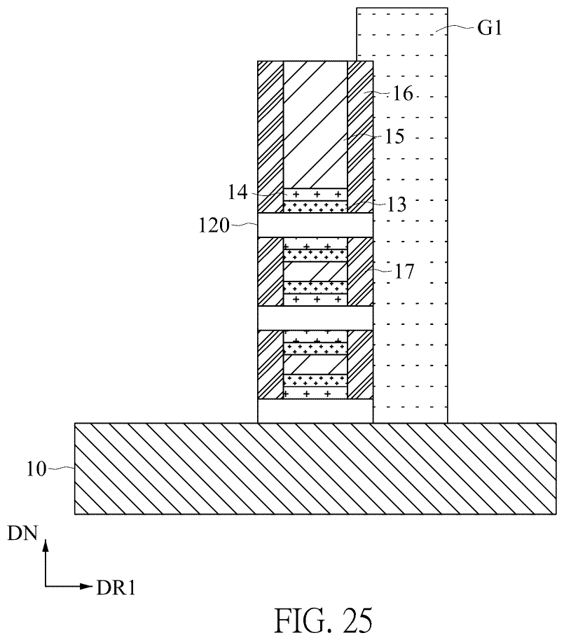

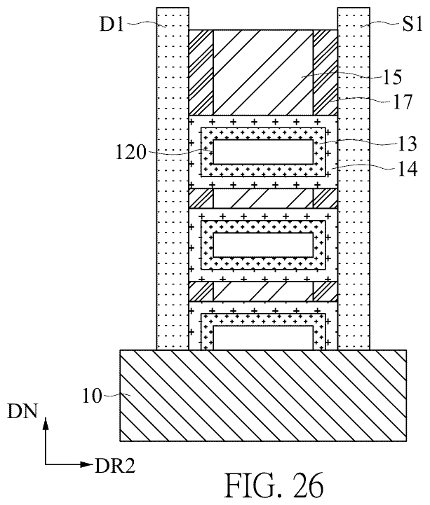

Reference is made to FIGS. 24 to 26, in which FIG. 24 is a top view of process S16 according to the first embodiment of the present disclosure, FIG. 25 is a first cross-sectional view of process S16 according to the first embodiment of the present disclosure, and FIG. 26 is a second cross-sectional view of process S16 according to the first embodiment of the present disclosure.

Before process S16 is performed, the two exposed outer surfaces of each channel layer 14 (i.e., two surfaces respectively on the third side and the fourth side) may be doped with either n-type or p-type dopants along the second direction DR2, so that an n⁺ region or a p⁺ region is formed at predetermined locations of drain and source regions on each channel layer 14. The n+ region or the p+ region may be formed in high selective ion implantation (HiSIDE) or other manners. Then, a drain component D1 and a source component S1 may be formed respectively on the third side and the fourth side, and may be electrically connected to each channel layer 14. The drain component D1 and the source component S1 may include TiN, A1, Ti, W, indium tin oxide (ITO), indium oxide (InO) or another material. The thickness of both the drain component D1 and the source component S1 may fall within a range from 1 nm to 1000 nm, and may be deposited by ALD or sputtering As shown in FIG. 24, the drain component D1 and the source component S1 may be formed as two strip-shaped metal sheets that extend along the vertical direction DN and are electrically connected to each channel layer 14. Each strip-shaped metal sheet has a height that is slightly greater than that of the protection layer 15 and the inner spacer layer 17. In addition, the drain component D1 and the source component S1 have a larger contact area with the two exposed outer surfaces of the channel layer 14, such that a resistance of a series resistor can be reduced and performance of both the drain component D1 and the source component S1 is improved.

On the other hand, a first gate component G1 may be formed on the first side and electrically connected to each gate metal layer 120. Similarly, the first gate component G1 may include TiN, A1, Ti, W, indium tin oxide (ITO), indium oxide (InO) or another material. The first gate component G1 may have a thickness falling within a range of 1 nm to 1000 nm, and may be deposited by ALD or sputtering. As shown in FIG. 23, the first gate component G1 may be formed as one strip-shaped metal sheet that extends along the vertical direction DN and is electrically connected to each gate metal layer 120. In some embodiments, after the first gate component G1, the drain component D1 and the source component S1 are formed, processes S17 and S18 may be performed.

In process S17, a dielectric layer is formed to cover the first gate component, the drain component, the source component, and the inner spacer layer on the first side of the second fin.

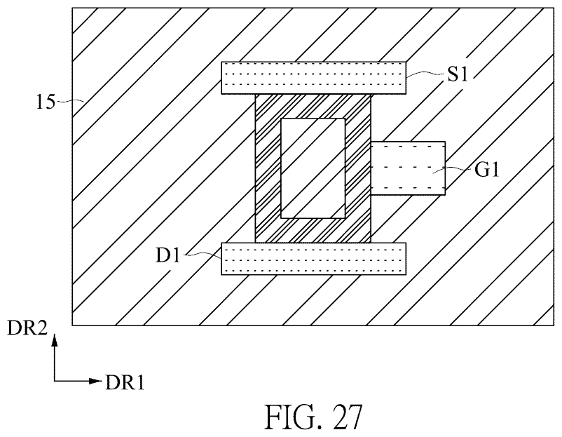

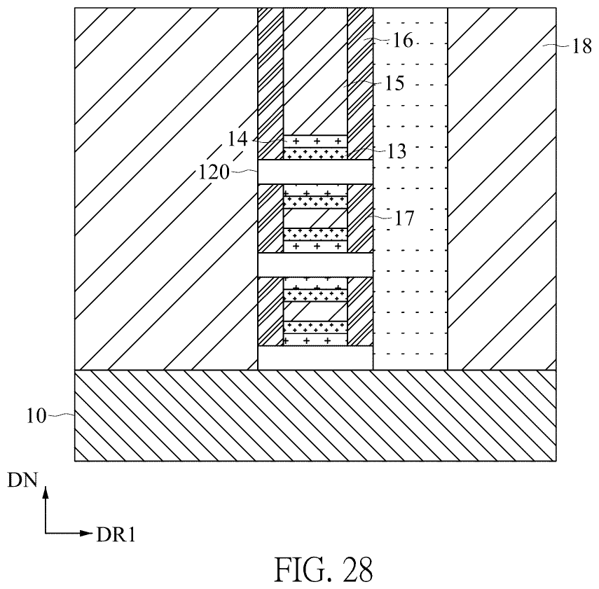

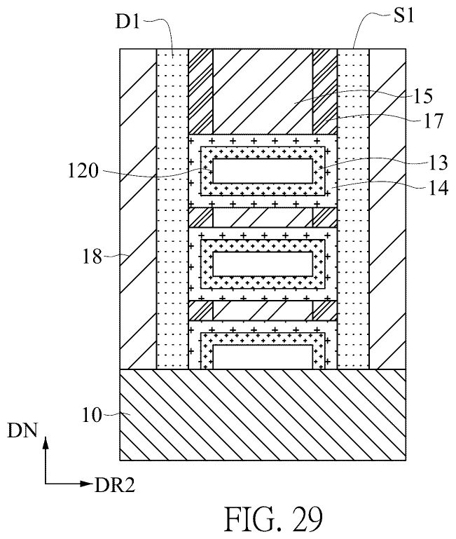

Reference is made to FIG. 27 to FIG. 29, in which FIG. 27 is a top view of processes S17 and S18 according to the first embodiment of the present disclosure, FIG. 28 is a first cross-sectional view of processes S17 and S18 according to the first embodiment of the present disclosure, and FIG. 29 is a second cross-sectional view of processes S17 and S18 according to the first embodiment of the present disclosure.

In process S17, a dielectric layer 18 may be uniformly formed on a structure surface by using chemical vapor deposition (CVD), plasma-enhanced chemical vapor deposition (PECVD) or atomic layer deposition (ALD). The dielectric layer usually includes silicon dioxide (SiO₂), silicon nitride (Si₃N₄), hafnium dioxide (HfO₂), or other materials having excellent insulating properties.

In process S18, the dielectric layer, the protection layer, the inner spacer layers, the first gate component, the drain component and the source component are partially removed in the vertical direction by a grinding procedure.

As shown in FIGS. 27 to 29, in process S18, a chemical mechanical polishing (CMP) process may be performed, for example, to precisely remove excess materials in the vertical direction DN. In the CMP process, a planarization effect is achieved on surfaces of the dielectric layer 18, the protection layer 15, the inner spacer layer 17, the first gate component G1, the drain component D1, and the source component S1 by performing both mechanical grinding and chemical etching. After the CMP process is performed, unnecessary top portions of the dielectric layer 18, the protection layer 15, the inner spacer layer 17, the first gate component G1, the drain component D1 and the source component S1 are removed for subsequent processes.

In process S19, portions of the plurality of inner spacer layers and each protection layer are removed from the second side to expose each gate metal layer, each first gate insulating layer, each channel layer and each inner spacer layer that is not removed.

For example, in process S19, portions of the inner spacer layer 17 and the dielectric layer 18 on the second side, the protection layers 15, and portions of the drain component D1 and the source component S1 may be removed by an etching procedure.

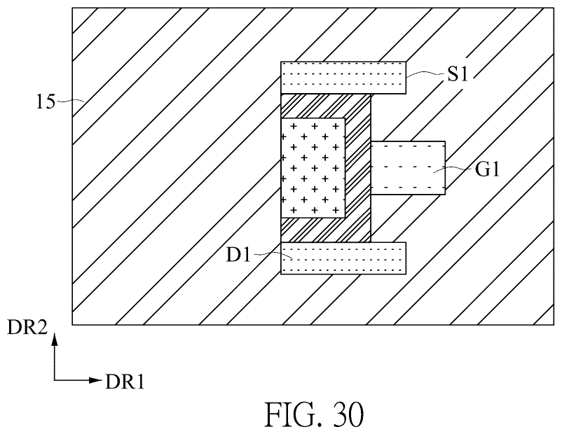

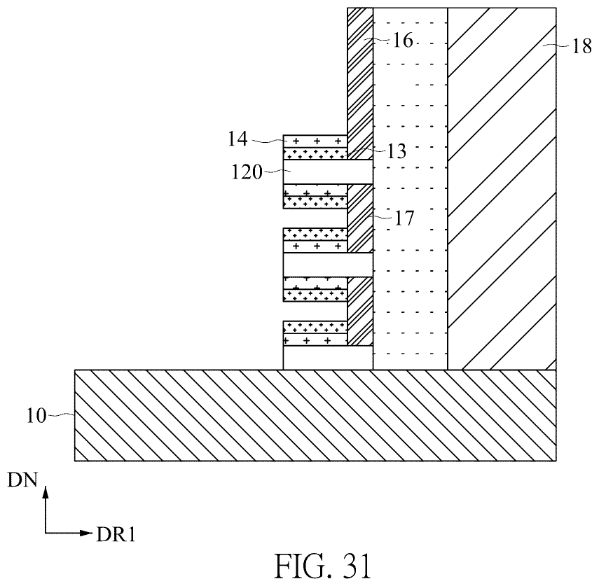

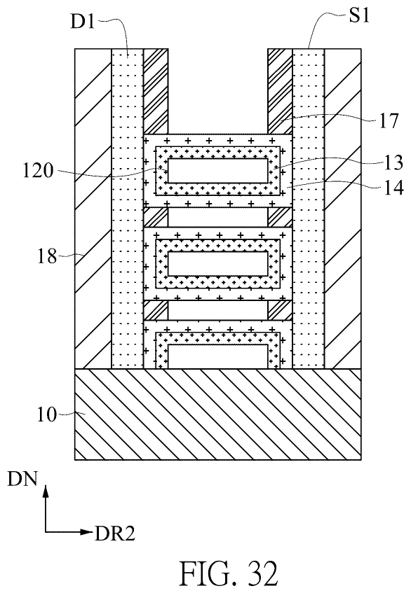

Reference is made to FIG. 30 to FIG. 32, in which FIG. 30 is a top view of process S19 according to the first embodiment of the present disclosure, FIG. 31 is a first cross-sectional view of process S19 according to the first embodiment of the present disclosure, and FIG. 32 is a second cross-sectional view of process S19 according to the first embodiment of the present disclosure.

In process S19, reactive ion etching (RIE) and/or wet etching may be used for accurately removing materials from a target region. For example, the highly anisotropic characteristics of reactive ion etching (RIE) may be utilized in a process in which fluorine-based gases (such as SF₆ or CF₄) are introduced to etch the dielectric layer 18, while chlorine-based gases (such as Cl₂ or BCl₃) are used to etch metal materials.

In some embodiments, a hydrofluoric acid (HF) solution may be used to remove the inner spacer layer 17, or a mixed solution of ammonia and hydrogen peroxide (SC-1) may be used to remove a portion of a specific metal component. Wet etching has good selectivity when processing complex structures. In some embodiments, a hydrofluoric acid (HF) solution may be used to remove the inner spacer layer 17, or a mixed solution of ammonia and hydrogen peroxide (SC-1) may be used to remove a portion of a specific metal component. Wet etching offers good selectivity when processing complex structures.

In the etching procedure described above, a photoresist or a hard mask may be applied according to process requirements to accurately and selectively remove the inner spacer layer 17 and a portion of the dielectric layer 18 on the second side. At the same time, the drain component D1 and the source component S1 are partially removed to expose portions of the gate metal layer 120 and the first gate insulating layer 13 that faces the second side, a portion of that faces the second side, a portion of a surface of the channel layer 14, and the inner spacer layer 17. Specifically, the main purpose of this process is to release the channel layer 14 and simultaneously expose a specific surface of the gate metal layer 120 for forming the back gate as a body contact.

In process S20, a second gate insulating layer, a plurality of gate connectors and a second gate component are formed sequentially on each exposed gate metal layer, each exposed first gate insulating layer, each exposed channel layer and each exposed spacer layer that is not removed.

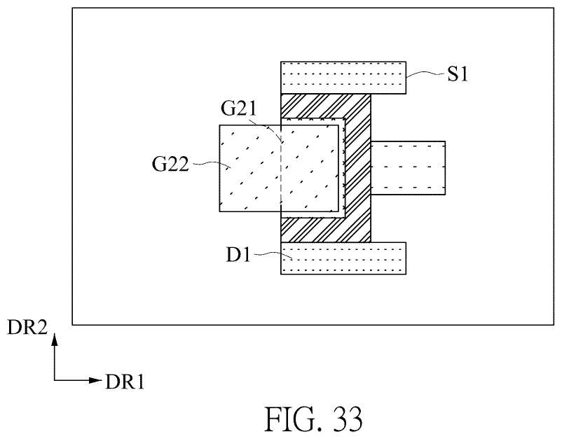

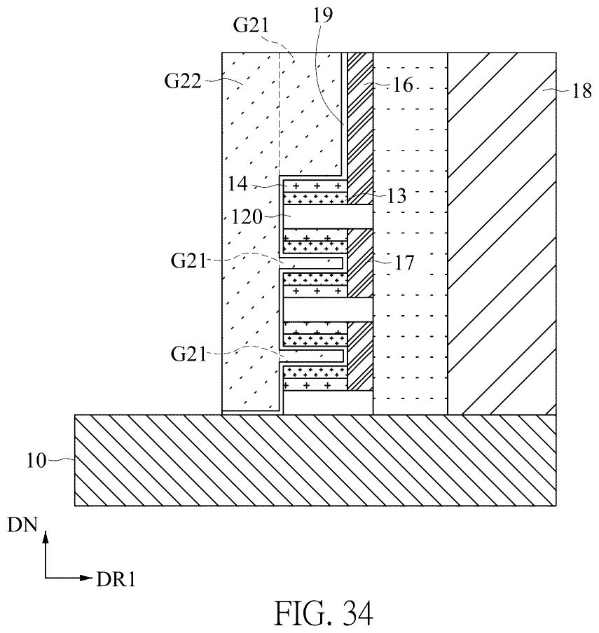

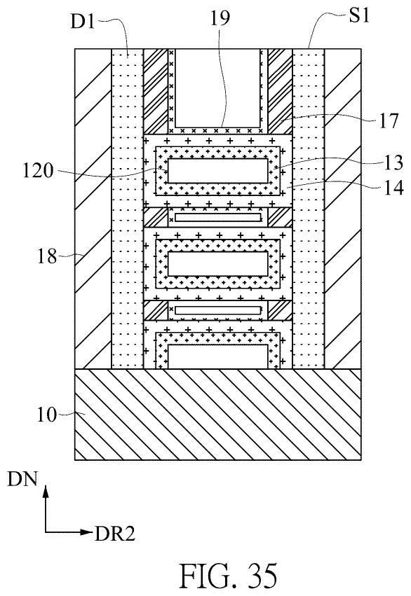

Reference is made to FIG. 33 to FIG. 35, in which FIG. 33 is a top view of process S20 according to the first embodiment of the present disclosure, FIG. 34 is a first cross-sectional view of process S20 according to the first embodiment of the present disclosure, and FIG. 35 is a second cross-sectional view of process S20 according to the first embodiment of the present disclosure.

Similar to the first gate insulating layer 13, a second gate insulating layer 19 may include a high-k dielectric material such as aluminum oxide (A1₂O₃), hafnium oxide (HfO₂), zirconium oxide (ZrO₂) or hafnium zirconium oxide (HZO). The second gate insulating layer 19 may have a thickness falling within a range of 1 nm to 1000 nm, and may be deposited using such the atomic layer deposition (ALD) or other techniques. As shown in FIG. 33 to FIG. 35, the second gate insulating layer 19 may be formed on the exposed surfaces of each exposed gate metal layer 120, each exposed first gate insulating layer 13, each exposed channel layer 14 and a surface of each exposed inner spacer layer 17 that is not removed and faces the second side. In addition, since the portion of the substrate 10 that is exposed by removing the dielectric layer 18 and the portion of the first one of the plurality of gate metal layers 120 in process S19 is covered by the second gate insulating layer 19, the first sectional view of FIG. 34 shows that the second gate insulating layer 19 has a comb teeth like structure.

On the other hand, a plurality of gate connectors G21 and a second gate component G22 may be formed on the second side and electrically connected to each gate metal layer 120. Similarly, the gate connector G21 and the second gate component G22 may include TiN, A1, Ti, W, indium tin oxide (ITO), indium oxide (InO) or another material, and may be deposited by ALD or sputtering. As shown in FIG. 33, the second gate component G22 extends along the vertical direction, the plurality of gate connectors G21 branch from the second gate component G22, and each gate connector G21 extends along the first direction DR1. Therefore, the plurality of gate connectors G21 and the second gate component G22 together form a comb-shaped conductive structure electrically connected to each gate metal layer 120. In addition, each comb-tooth structure is disposed between two adjacent ones of the plurality of channel layers 14, between two adjacent ones of the plurality of first gate insulating layers 13, and between two adjacent ones of the plurality of gate metal layers 120. Here, the gate connector G21 and the second gate component G22 may serve as body contacts for adjusting the threshold voltage.

After process S20 is performed, the dielectric layer may be removed by etching or grinding according to electrode configuration requirements, to form the split double gate transistor provided in the present disclosure.

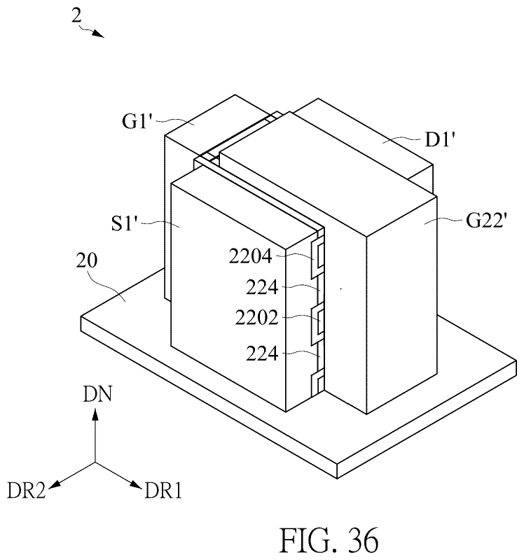

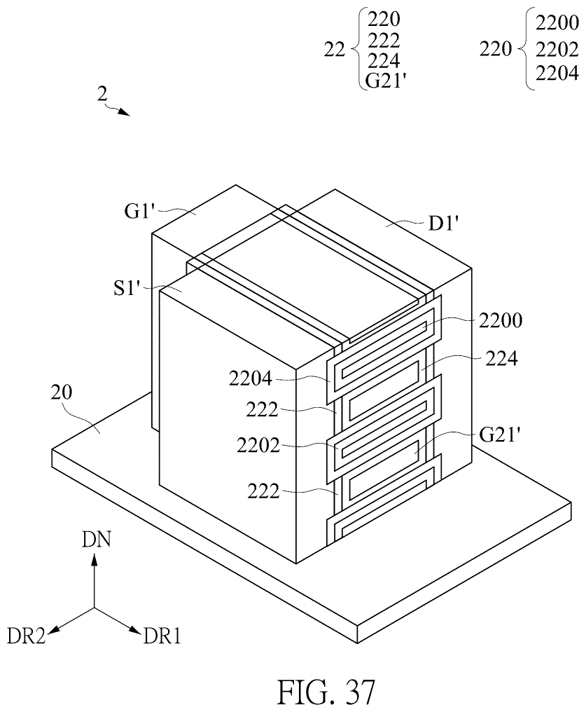

Reference is made to FIG. 36 and FIG. 37, in which FIG. 36 is a perspective view of a split double gate transistor according to a second embodiment of the present disclosure, and FIG. 37 is a perspective view of the split double gate transistor from which a second gate component is removed according to the second embodiment of the present disclosure.

As shown in FIGS. 36 and 37, in the second embodiment, the present disclosure provides the split double gate transistor 2, which includes a substrate 20, a fin-shaped structure 22, a first gate component G1′, a drain component D1′, a source component D2′ and a second gate component G22′.

The fin-shaped structure 22 is disposed on the substrate 20 and includes a plurality of stacked structures 220, a plurality of gate connectors G21′, a plurality of inner spacers 222 and a second gate insulating layer 224.

The plurality of stacked structures 220 are spaced apart along the vertical direction DN. Each stacked structure 220 includes a gate metal layer 2200, a first gate insulating layer 2202 and a channel layer 2204.

The plurality of gate connectors G21′ are alternately arranged with the plurality of stacked structures 220 along the vertical direction DN, and each gate connector G21′ extends along the first direction DR1.

The plurality of inner spacers 222 are spaced apart along the vertical direction DN, respectively surround the plurality of gate connectors G21′, and are in contact with each first gate insulating layer 2202 and each channel layer 2204.

The second gate insulating layer 224 is disposed between each inner spacer 222 and the gate connector G21′ surrounded thereby, and disposed between each of the plurality of gate connectors G21′ and the stacked structure 220 disposed adjacent thereto. In a first portion of the second gate insulating layer 224, which extends along the first direction DR1 and the second direction DR2, a first sub-portion is in contact with the channel layer 2204, while a second sub-portion is in contact with the substrate 20. In a second portion of the second gate insulating layer 224, which extends along the vertical direction DN, a third sub-portion is in contact with each inner spacer 222, while a fourth sub-portion is in contact with each stacked structure 22.

The first gate component G1′ is disposed on the first side of the fin-shaped structure 22 and electrically connected to each gate metal layer 2200.

The drain component D1′ and the source component S1′ are respectively arranged on the third side and the fourth side opposite to the fin-shaped structure 22 along the second direction DR2. The drain component D1′ is electrically connected to the drain region of each channel layer 2204, and the source component S1′ is electrically connected to the source region of each channel layer 2204.

The second gate component G22′ is disposed on the second side of the fin-shaped structure 22 and is electrically connected to each gate connector G21′.

Specific morphologies and materials of the substrate 20, the fin-shaped structure 22, the gate connectors G21′, the inner spacers 222, the second gate insulating layers 224, the gate metal layers 2200, the first gate insulating layer 2202, the channel layers 2204, the first gate component G1′, the drain component D1′, the source component D2′ and the second gate component G22′ may be the same as those shown in FIGS. 31 to 33 and described herein, and thus are not repeated here.

The split double gate transistor provided by the present disclosure includes a back gate that can be used to adjust the threshold voltage, thereby improving performance of an electronic device incorporating the transistor. For example, when the split double gate transistor provided by the present disclosure is applied to a conventional 2T0C memory architecture, a body voltage applied to the second gate component may be adjusted to an operating voltage (such as a common voltage of VDD), thereby increasing a conduction current and improving a writing speed.

Alternatively, the body voltage applied to the second gate component may be adjusted to a negative operating voltage (−VDD), thereby reducing a leakage current when a switch is turned off and increasing a data retention time in a storage node.

### Beneficial Effects of the Embodiments

One beneficial effect of the present disclosure is that, the present disclosure provides the split double gate transistor and the method for manufacturing the same, in which all the channel layers are deposited simultaneously to form the transistors each having the threshold voltage that is adjustable through the back gate, thereby reducing process variations.

Furthermore, when the split double gate transistor of the present disclosure is applied to a conventional memory architecture, the body voltage applied to the second gate component may be adjusted to the operating voltage (such as the VDD), thereby increasing the conduction current and improving the writing speed. Alternatively, the body voltage applied to the second gate component may be adjusted to the negative operating voltage (−VDD), thereby reducing leakage current when the switch is turned off and increasing the data retention time in the storage node.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A method for manufacturing a split double gate transistor, comprising processes of:
forming a first fin including a plurality of gate metal layers and a plurality of sacrificial layers that are stacked alternately on a substrate;
removing the plurality of sacrificial layers from a portion of the first fin;
sequentially forming a first gate insulating layer, a channel layer and a protection layer on an exposed portion of each of the plurality of gate metal layers;
patterning the first fin, the first gate insulating layer, the channel layer and the protection layer to form a second fin;
patterning the second fin to form a plurality of first recesses on a first side and a second side and a plurality of second recesses on a third side and a fourth side;
forming a plurality of inner spacer layers to fill in the plurality of first recesses and the plurality of second recesses;
forming a first gate component connected electrically to the plurality of gate metal layers on the first side, a drain component connected electrically to the channel layer on the third side, and a source component connected electrically to the channel layer on the fourth side;
removing a portion of the plurality of inner spacer layers and the protection layer from the second side, to expose each of the plurality of gate metal layers, the first gate insulating layer, the channel layer, and each of the plurality of inner spacer layers that are not removed; and
sequentially forming a second gate insulating layer, a plurality of gate connectors and a second gate component, on each of the plurality of gate metal layers, the first gate insulating layer and the channel layer that are exposed, and on each of the plurality of inner spacer layers that are not removed.

2. The method for manufacturing the split double gate transistor according to claim 1, wherein the first fin covers a first region of the substrate, and the first fin, the first gate component, the second gate component, the drain component and the source component extend along a vertical direction.

3. The method for manufacturing the split double gate transistor according to claim 1, wherein the process of removing the plurality of sacrificial layers from the portion of the first fin includes:
removing a portion of the plurality of sacrificial layers that is located outside a first region of the substrate from the first fin to expose a portion of the plurality of gate metal layers.

4. The method for manufacturing the split double gate transistor according to claim 1, wherein the process of patterning the first fin, the first gate insulating layer, the channel layer and the protection layer to form the second fin includes:
partially removing the first fin, the first gate insulating layer, the channel layer and the protection layer that are located outside a second region that partially overlaps with a first region of the substrate, such that a remaining portion within the second region forms a second fin.

5. The method for manufacturing the split double gate transistor according to claim 1, wherein the process of patterning the second fin to form the plurality of first recesses and the plurality of second recesses includes:
partially removing the first gate insulating layer, the channel layer and the protection layer from the second fin along a first direction, so that the first gate insulating layer, the channel layer and the protection layer are recessed beyond the plurality of gate metal layers to form the plurality of first recesses; and
removing another portion of the protection layer from the second fin along a second direction, so that the protection layer is recessed beyond the plurality of gate metal layers, the gate insulating layer and the channel layer to form the plurality of second recesses.

6. The method for manufacturing the split double gate transistor according to claim 5, wherein the first direction, the second direction and the vertical direction are perpendicular to each other.

7. The method for manufacturing the split double gate transistor according to claim 1, further comprising processes of:
after the first gate component, the drain component and the source component are formed, forming a dielectric layer to cover the first gate component, the drain component and the source component and the plurality of inner spacer layers on the first side of the second fin;
partially removing the dielectric layer, the protection layer, the plurality of inner spacer layers, the first gate component, the drain component and the source component in a vertical direction, by a grinding procedure;
partially removing the plurality of inner spacer layers and the dielectric layer on the second side, the protection layer, a portion of the drain component and a portion of the source component, by an etching procedure.

8. The method for manufacturing the split double gate transistor according to claim 1, wherein the first gate component is electrically connected to the plurality of gate metal layers at a plurality of positions along the vertical direction.

9. The method for manufacturing the split double gate transistor according to claim 8, wherein the channel layer and the first gate insulating layer are arranged between each of the plurality of gate metal layers and the drain component or the source component.

10. The method for manufacturing the split double gate transistor according to claim 1, wherein the first gate insulating layer, the channel layer, the second gate insulating layer, the second gate component, the second gate insulating layer, the channel layer and the first gate insulating layer are sequentially arranged between two adjacent ones of plurality of gate metal layers.

11. A split double gate transistor, comprising:
a substrate;
a fin-shaped structure disposed on the substrate and includes:
a plurality of stacked structures arranged at intervals along a vertical direction, wherein each of the plurality of stacked structures includes a gate metal layer, a first gate insulating layer and a channel layer;
a plurality of gate connectors arranged alternately with the plurality of stacked structures along the vertical direction and extend along a first direction;
a plurality of inner spacers, wherein the plurality of inner spacers are spaced apart from each other along the vertical direction, respectively surround the plurality of gate connectors, and are in contact with the first gate insulating layer and the channel layer; and
a second gate insulating layer disposed between the plurality of inner spacers and the plurality of gate connectors and between the plurality gate connectors and the plurality stacked structures;
a first gate component disposed on a first side of the fin-shaped structure and electrically connected to the gate metal layer;
a drain component and a source component, wherein the drain component is disposed on a second side opposite to the fin-shaped structure along a second direction and electrically connected to a drain region of the channel layer, and the source component is disposed on a third side opposite to the fin-shaped structure along the second direction and electrically connected to a source region of the channel layer; and
a second gate component disposed on the second side of the fin-shaped structure and electrically connected to the plurality of gate connectors.

12. The split double gate transistor according to claim 11, wherein the first gate component, the second gate component, the drain component and the source component extend along the vertical direction.

13. The split double gate transistor according to claim 12, wherein the first gate insulating layer, the channel layer and the protection layer are recessed beyond the plurality of gate metal layers along the first direction.

14. The split double gate transistor according to claim 11, wherein the first direction, the second direction and the vertical direction are perpendicular to each other.

15. The split double gate transistor according to claim 11, wherein the first gate component is electrically connected to the plurality of gate metal layers at a plurality of positions along the vertical direction.

16. The split double gate transistor according to claim 11, wherein the channel layer and the first gate insulating layer are arranged between each of the plurality of gate metal layers and the drain component or the source component.

17. The split double gate transistor according to claim 11, wherein the first gate insulating layer, the channel layer, the second gate insulating layer, the second gate component, the second gate insulating layer, the channel layer and the first gate insulating layer are sequentially arranged between two adjacent ones of the plurality of gate metal layers.
